(19) United States
(12) Patent Application Publication
(10) Pub. No.: US 2015/0267291 A1
(43) Pub. Date: Sep. 24, 2015

(54) PURGE CHAMBER, AND SUBSTRATE-PROCESSING APPARATUS INCLUDING SAME

(71) Applicant: EUGENE TECHNOLOGY CO., LTD., Cheoin-gu, Yongin-si Gyeonggi-do (KR)

(72) Inventors: Il-Kwang Yang, Gyeonggi-do (KR); Byoung-Gyu Song, Gyeonggi-do (KR); Kyong-Hun Kim, Gyeonggi-do (KR); Yong-Ki Kim, Chungcheongnam-do (KR); Yang-Sik Shin, Gyeonggi-do (KR)

(73) Assignee: EUGENE TECHNOLOGY CO., LTD., Gyeonggi-do (KR)

(21) Appl. No.: 14/436,247

(22) PCT Filed: Nov. 1, 2013
(86) PCT No.: PCT/KR2013/009858

§ 371 Date: Apr. 16, 2015

(30) Foreign Application Priority Data
Nov. 1, 2012 (KR) 10-2012-0123116

(51) Int. Cl. C23C 16/44; C23C 16/455; C23C 16/458; C23C 16/02

(52) U.S. Cl. CPC C23C 16/4401; C23C 16/4412; C23C 16/0227; C23C 16/45559; C23C 16/4583

(57) ABSTRACT

Provided is a substrate processing apparatus including a process chamber in which a process for processing a substrate are processed, a purge chamber removing contaminants existing on the substrate, and a transfer chamber connected to a side surface of each of the process chamber and the purge chamber, the transfer chamber including a substrate handler transferring the substrate, on which the process is performed, into the purge chamber between the process chamber and the purge chamber, wherein the purge chamber includes a chamber having an inner space and a passage through which the substrate is taken in or out of the inner space, a substrate holder on which the substrate is placed, the substrate holder being disposed in the chamber, a gas supply port disposed on a side surface with respect to the passage to supply a gas toward the inner space, and an exhaust port disposed on a side opposite to the gas supply port to discharge the gas within the inner space.

### TECHNICAL FIELD

The present disclosed herein relates to a substrate processing apparatus and a purge chamber, and more particularly, to an apparatus for removing contaminants existing on a substrate, which is processed by a predetermined process, by using a purge chamber disposed on one side of a transfer chamber.

### BACKGROUND ART

Generally, in semiconductor device manufacturing processes, unit processes such as a deposition process, a photolithography process, an etching process, an ion injection process, a polishing process, a cleaning process, and the like may be repeatedly performed on a silicon substrate that is used as a substrate to form circuit patterns having desired electrical properties. In case of a dichloro silane (SiCl₂H₂) process for depositing a substrate, a chemical reaction may be performed as follows:

(SiH₂Cl₂+2N₂O→SiO₂+2N↑+2HCl) Reaction Formula (1)

As shown in Reaction Formula (1), a silicon oxide (SiO₂) layer is formed on a substrate on which a process of depositing the dichloro silane (SiCl₂H₂: DCS) and nitrogen oxide (2N₂O) are performed. On the other hand, when HCl absorbed on a surface of the substrate is transferred into an equipment front end module (EFEM), the HCl reacts with moisture within the EFEM to generate hydrochloric acid. Thus, the hydrochloric acid may corrode a metal within the EFEM. Particularly, in case of the single-wafer-type process cleaning the substrates one by one, the process may be quickly performed when compared to the batch-type process. Thus, the corrosive gas (e.g., HCl) generated from the substrate may increase in remaining amount to significantly corrode peripheral components and devices.

Also, when the fume of the substrate on which the deposition process is performed moves into an accommodation container for accommodating the plurality of substrates without being removed, the fume may be transferred onto other substrates within the accommodation container to cause contamination of the substrates.

### DISCLOSURE

### Technical Problem

The present invention provides an apparatus for transferring a processed substrate into a purge chamber to remove fume.

The present invention also provides an apparatus for removing fume generated from a processed substrate to prevent peripheral devices from being corroded.

Further another object of the present invention will become evident with reference to following detailed descriptions and accompanying drawings.

### Technical Solution

Embodiments of the present invention provide substrate processing apparatuses including: a process chamber in which a process for processing a substrate are processed; a purge chamber removing contaminants existing on the substrate; and a transfer chamber connected to a side surface of each of the process chamber and the purge chamber, the transfer chamber including a substrate handler transferring the substrate, on which the process is performed, into the purge chamber between the process chamber and the purge chamber, wherein the purge chamber includes: a chamber having an inner space and a passage through which the substrate is taken in or out of the inner space; a substrate holder on which the substrate is placed, the substrate holder being disposed in the chamber; a gas supply port disposed on a side surface with respect to the passage to supply a gas toward the inner space; and an exhaust port disposed on a side opposite to the gas supply port to discharge the gas within the inner space.

In some embodiments, the purge chamber may further include at least one diffusion plate disposed on a sidewall of the chamber connected to the gas supply port to diffuse the gas supplied through the gas supply port.

In other embodiments, the substrate holder may include: one or more loading plate having an opening with a shape corresponding to that of the substrate, an opening part defined in a side of the passage to communicate with the opening, and a seat groove defined along a circumference of the opening, wherein the one or more loading plats are vertically stacked on each other; and a holder cover disposed spaced upward from the loading plate, the holder cover vertically partitioning the inner space.

In still other embodiments, the substrate holder may include: an upper frame disposed above the substrate; a lower frame disposed under the substrate; and at least one support rod connecting the upper frame to the lower frame, the at least one support rod having a plurality support slots, in which an edge of the substrate is accommodated, defined along a length direction thereof.

In even other embodiments, the purge chamber may further include at least one baffle disposed on a sidewall of the chamber, to which the exhaust port is connected, to discharge the gas within the inner space.

In yet other embodiments, the gas may have a flow direction perpendicular to an entrance direction of the substrate.

In further embodiments, the gas may include an inert gas.

In still further embodiments, the purge chamber may further include a refrigerant passage in which a refrigerant is supplied.

In other embodiments of the present invention, the purge chamber includes: a chamber including an inner space and a passage through which a substrate is taken in or out of the inner space; a substrate holder on which the substrate is placed, the substrate holder being disposed within a chamber; a gas supply port disposed a side surface with respect to the passage to supply a gas toward the inner space; and an exhaust port disposed a side opposite to the gas supply port to discharge the gas within the inner space, wherein the substrate holder includes: one or more loading plate having an opening with a shape corresponding to that of the substrate, an opening part defined in a side of the passage to communicate with the opening, and a seat groove defined along a circumference of the opening, wherein the one or more loading plats are vertically stacked on each other; and a holder cover disposed spaced upward from the loading plate, the holder cover vertically partitioning the inner space.

In still other embodiments of the present invention, the purge chamber includes: a chamber including an inner space and a passage through which a substrate is taken in or out of the inner space; a substrate holder on which the substrate is placed, the substrate holder being disposed within a chamber; a gas supply port disposed a side surface with respect to the passage to supply a gas toward the inner space; and an exhaust port disposed a side opposite to the gas supply port to discharge the gas within the inner space, wherein the substrate holder includes: an upper frame disposed above the substrate; a lower frame disposed under the substrate; and at least one support rod connecting the upper frame to the lower frame, the at least one support rod having a plurality support slots, in which an edge of the substrate is accommodated, defined along a length direction thereof.

### Advantageous Effects

According to the embodiments of the present invention, since the processed substrate is transferred into the separate purge chamber to remove the fume remaining on the substrate, the corrosion of the peripheral devices may be prevented. Also, although the substrate is exposed to the atmosphere, it is unharmful to the human body. Also, since the fume of the substrate on which the process is completed is removed, faulty of the substrates due to the fume may be prevented, and the yield of products may be improved.

### DESCRIPTION OF DRAWINGS

FIG. 1 is a view illustrating a position at which a purge chamber is installed;

FIG. 2 is a schematic view of a purge chamber according to an embodiment of the present invention;

FIG. 3 is a view of a substrate holder according to an embodiment of the present invention;

FIG. 4 is a view illustrating a gas flow within the purge chamber in which the substrate holder of FIG. 3 is disposed;

FIG. 5 is a view of a substrate holder according to another embodiment of the present invention; and

FIG. 6 is a rear view illustrating a gas flow within the purge chamber in which the substrate holder of FIG. 5 is disposed.

### BEST MODE

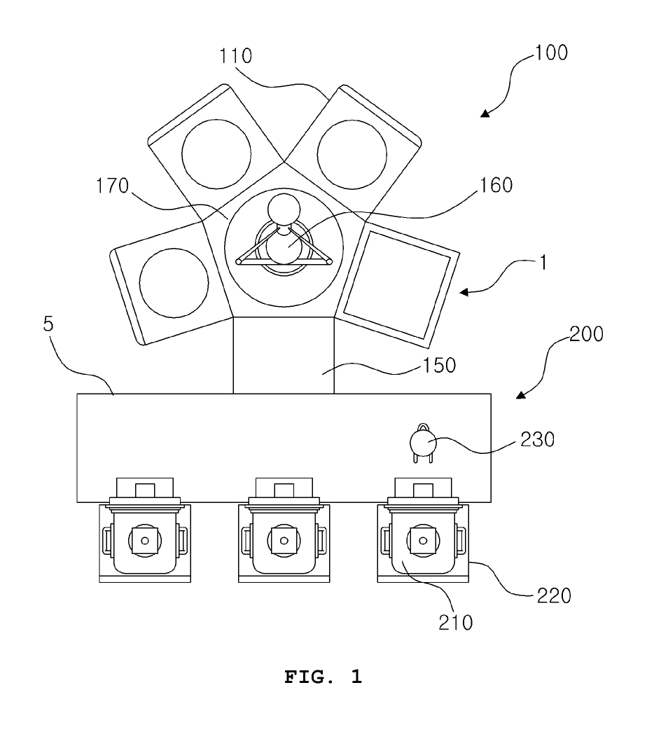

Hereinafter, exemplary embodiment of the present invention will be described in detail with reference to FIGS. 1 to 4. The present invention may, however, be embodied in different forms and should not be constructed as limited to the embodiments set forth herein. Rather, this embodiment is provided so that this disclosure will be thorough and complete, and will fully convey the scope of the present invention to those skilled in the art. In the drawings, the shapes of components are exaggerated for clarity of illustration.

FIG. 1 is a view illustrating a position at which a purge chamber is installed. Referring to FIG. 1, a substrate manufacturing facility in which processes with respect to substrates are performed includes process chambers 110 in which processing processes with respect to a substrate W is performed and an equipment front end module (EFEM) 200 through which the substrate W is loaded into or unloaded from the process chamber 110. A substrate processing apparatus 100 includes a purge chamber 1, a plurality of process chambers 110, a transfer chamber 170, and a substrate handler 160 disposed in the transfer chamber 170 to transfer the substrate W between the process chambers 110 and the purge chamber 1. Vacuum gate valves (not shown) are disposed among the transfer chamber 170, the purge chamber 1, and the process chambers 110. The vacuum gate valves are opened or closed to transfer the substrate W from the transfer chamber 170 to the purge chamber 1 or the process chambers 110.

Each of the process chambers 110 receives the substrate W to perform a semiconductor process, e.g., an etching process, a cleaning process, an ashing process, and the like, thereby processing the substrate W. The transfer chamber 170 may have a generally polygonal shape when viewed from an upper side. Also, the transfer chamber 170 is connected to the purge chamber 1, each of the process chambers 110, and a loadlock chamber 150. The substrate handler 160 may be disposed within the transfer chamber 170. The substrate handler may load the substrate W into the purge chamber 1 and each of the process chambers 110 or unload the substrate W from the purge chamber 1 and each of the process chambers 110. Also, the substrate handler 160 may transfer the substrate W among the purge chamber 1, each of the process chambers 110, and the loadlock chamber 150.

The loadlock chamber 150 is disposed between the transfer chamber 170 and the EFEM 200. The loadlock chamber 150 may include a loading chamber (not shown) in which the substrates W loaded into the purge chamber 1 and the process chambers 110 temporarily stay and an unloading chamber (not shown) in which the processed substrates W loaded from the purge chamber 1 and the process chambers 110 temporarily stay. Here, the inside of the loadlock chamber 150 may be converted into the vacuum or atmospheric state. However, the transfer chamber 170, the purge chamber 1, and the process chambers 110 are maintained in the vacuum state. Thus, the loadlock chamber 150 prevents external contaminants from being introduced into the purge chamber 1, the process chambers 110, and the transfer chamber 170.

The EFEM 200 includes a plurality of accommodation containers 210, a plurality of loadports 220, a frame 5, and a second transfer unit 230. The accommodation containers 210 may accommodate the plurality of substrates W. Here, each of the accommodation containers 210 provide the substrates W, which are not processed yet, into the substrate processing apparatus 100 and accommodate again the substrates W processed by the substrate processing apparatus 100. The accommodation container 210 is seated on the loadport 220, and the loadport 220 is disposed on a front side of the frame 5 to support the accommodation container 210.

The frame 5 may be disposed between the loadport 220 and the loadlock chamber 150, and the second transfer unit 230 may be disposed within the frame 5. The second transfer unit 230 transfers the substrate W between the accommodation containers 210 seated on the loadport 220 and the transfer chamber 170. The second transfer unit 230 takes the substrate W out of the accommodation container 210 to provide the substrate W into the transfer chamber 170. Also, the second transfer unit 230 receives the processed substrate W from the purge chamber 1 and the process chambers 110 to transfer the substrate W into the accommodation container 210.

In case of a dichlorosilane (DCS) process for processing a substrate, chemical reaction may be performed as follows:

(SiH₂Cl₂+2N₂O→SiO₂+2N↑+2HCl) Reaction Formula (1)

As shown in Reaction Formula (1), the silicon oxide (SiO₂) layer is formed on the substrate on which the DCS process is performed. On the other hand, when HCl absorbed on the surface of the substrate is transferred into the EFEM 200, the HCl reacts with moisture within the EFEM 200 to generate hydrochloric acid. Thus, the hydrochloric acid may corrode a metal within the EFEM 200. Particularly, in case of the single-wafer-type process cleaning the substrates W one by one, the process may be quickly performed when compared to the batch-type process. Thus, the corrosive gas (e.g., HCl) generated from the substrate W may increase in remaining amount to significantly corrode peripheral components and devices.

Also, when the fume of the substrate W on which the deposition process is performed moves into the accommodation container 210 for accommodating the plurality of substrates W without being removed, the fume may be transferred onto other substrates W within the accommodation container 210 to cause contamination of the substrates W. To solve the above-described limitation, the purge chamber 1 may be provided on a side of the transfer chamber 170 to remove the fume and corrosive gas which can contaminate the substrates W. The purge chamber 1 will be described with reference to following drawings.

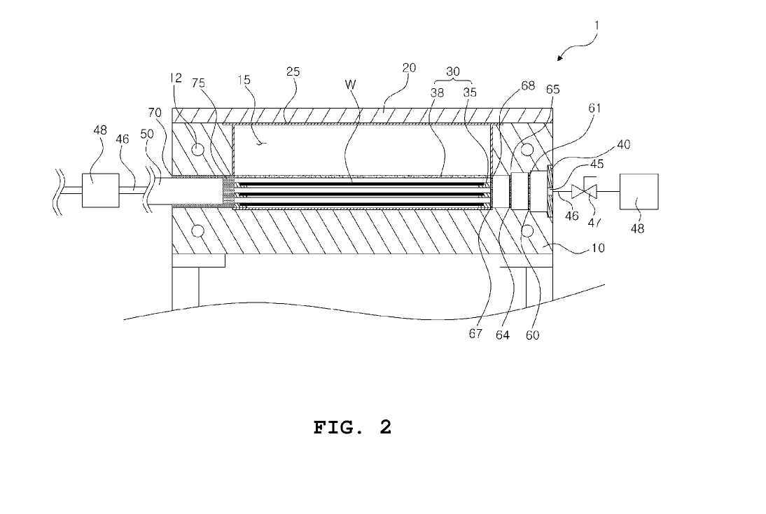

FIG. 2 is a schematic view of a purge chamber according to an embodiment of the present invention. As described above, the purge chamber 1 is connected to a side of the transfer chamber 170, and a passage (not shown) through which the substrate W is loaded and unloaded through opening/closing of the vacuum gate valves is defined in the purge chamber 1. The processed substrate W in the process chambers 110 is transferred into the purge chamber 1 by the substrate handler 160. The corrosive fume remains on the processed substrate W to corrode the peripheral devices. The processed substrate W may be instantly transferred into the purge chamber 1 to remove the corrosive fume, thereby preventing the peripheral devices from being corroded and preventing the fume from being exposed to the atmosphere.

Referring to FIG. 2, a chamber 10 has an opened upper side, and a chamber cover 20 is disposed on an upper portion of the chamber 10 to provide an inner space 15. The substrate holder 30 is disposed within the inner space 15, and the substrate W taken in or out through the passage is loaded on a substrate holder 30. A gas supply port 40 is disposed on a side surface with respect to the passage through which the substrate W is loaded and unloaded. The gas supply port 40 includes a gas supply hole 45, and the gas supply hole 45 is connected to a gas supply tube 146 to receive a gas from a gas supply storage tank 148. A valve 47 is disposed in the gas supply tube 146 to control a gas supply mount, and the gas is supplied into the inner space 15 through the gas supply hole 45. The gas may be an inert gas including as an argon (Ar) gas.

The purge chamber 1 may have a refrigerant passage 12 defined in and along a wall of the chamber 10. A refrigerant flows along the refrigerant passage 12, and cooling water or a cooling gas may be used as the refrigerant. Thus, the refrigerant may be supplied through the refrigerant passage 12 to cool the inside of the purge chamber 1. The refrigerant may be supplied into the refrigerant passage 12 through a refrigerant supply pipe connected to a refrigerant supply tank (not shown). The refrigerant may circulate along the refrigerant passage. The refrigerant heated after circulating in the chamber 10 may be introduced into a chiller along the refrigerant supply tube and then be re-cooled.

A plurality of diffusion plates are disposed on a side wall of the chamber 10 connected to the gas supply port 40. Referring to FIG. 2, first to third diffusion plates 60, 64, and 67 may respectively have a plurality of diffusion holes 61, 65, and 68 to successively diffuse and supply the gas supplied through the gas supply hole 45 toward the inner space 15. The first to third diffusion plates 60, 64, and 67 are disposed at a predetermined distance to uniformly diffuse and supply the gas supplied through the gas supply hole 45 toward the inner space 15.

An exhaust port 50 discharging the gas supplied through the gas supply port 40 is disposed on an opposite side of the gas supply port 40. The exhaust port 50 may be connected to an exhaust tube 46 to forcibly discharge the gas within the inner space 15 by an exhaust pump 48 connected to the exhaust tube 46. A baffle 70 having a plurality of discharge holes 75 is disposed on the exhaust port 50. A flow of the gas within the inner space 15 is constantly maintained through the discharge holes 75 to discharge the gas the outside. The gas supply port 40 and the exhaust port 50 are disposed on the both sides with respect to the passage, respectively. That is, the gas flows in a direction perpendicular to an entrance direction of the substrate W. Also, the baffle 70 may be provided in plurality on the exhaust port 50.

As described above, the substrate holder 30 is disposed within the inner space 15 of the chamber 10. The processed substrate W is guided into the inner space 15 of the purge chamber 1 through substrate handler 160 of the transfer chamber 170. The substrate W guided into the inner space 15 is loaded on the substrate holder 30. When the substrate is loaded, the inner space 15 is blocked by the vacuum gate valve (not shown). When the vacuum gate valve is closed, a gas is introduced through the gas supply hole 45, and then the introduced gas is discharged together with the fume remaining on the substrate W into the exhaust port 50.

Since the corrosive fume remaining on the substrate W corrodes an inner wall of the chamber 10, a cover 25 is disposed to protect the inner wall of the chamber 10. The cover 25 may be formed of quartz or a ceramic material. In addition, the substrate holder 30 supporting the substrate W may be formed of the quartz or the ceramic material. The substrate holder 30 and mounting effects of the substrate holder 30 will be described with reference to following drawings.

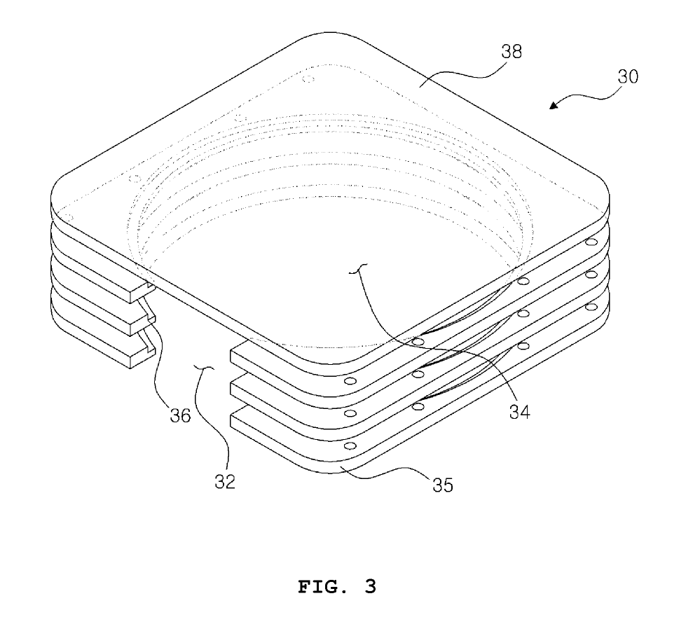

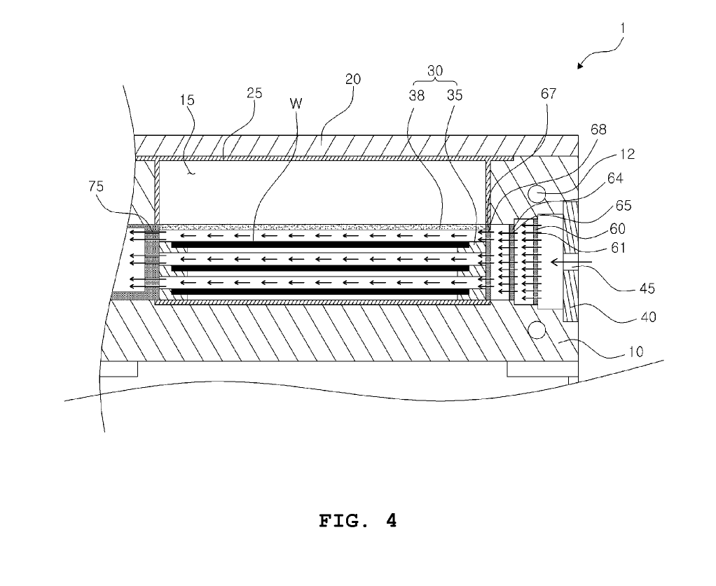

FIG. 3 is a view of the substrate holder according to an embodiment of the present invention. FIG. 4 is a view illustrating a gas flow within the purge chamber in which the substrate holder of FIG. 3 is disposed. Referring to FIG. 3, a loading plate 35 has an opening 34 having a shape corresponding to that of the substrate W. Also, an opening part 32 is defined in a side of the passage in which the substrate W is loaded and unloaded to communicate with the opening 34. A seat groove 36 is defined in the loading plate 35 along a circumference of the opening 34. The substrate W guided into the inner space 15 contacts the seat groove 36 and is supported by the seating groove 36. One or more loading plates 35 may be provided and be vertically stacked on each other. For example, three loading plates 35 may be provided to accommodate three substrates W.

A holder cover 38 is connected to an upper portion of the uppermost loading plate 35. Referring to FIG. 4, the holder cover 38 may vertically partition the inner space 15. The most of gas introduced through the diffusion plates 60, 64, and 67 may be supplied onto the substrate W to sufficiently remove the fume remaining on the substrate by minimizing a gas flow space through the holder cover 38.

Although the present invention is described in detail with reference to the exemplary embodiment, the invention may be embodied in many different forms. Thus, technical idea and scope of claims set forth below are not limited to the preferred embodiment.

### MODE FOR INVENTION

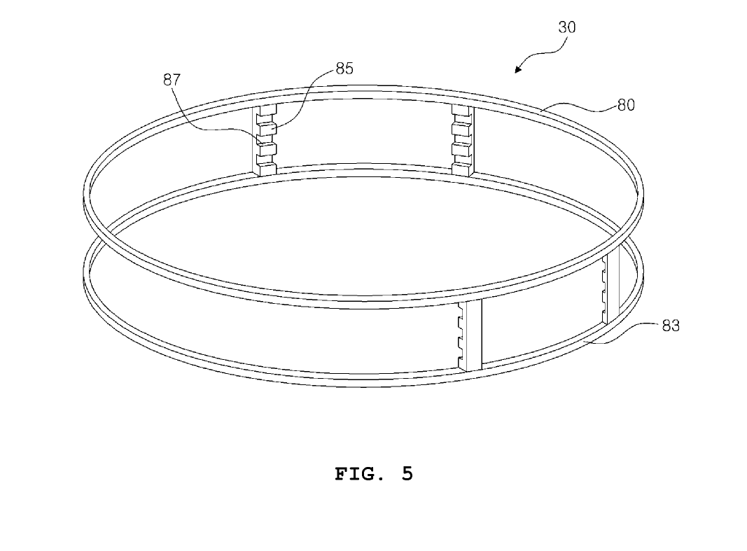

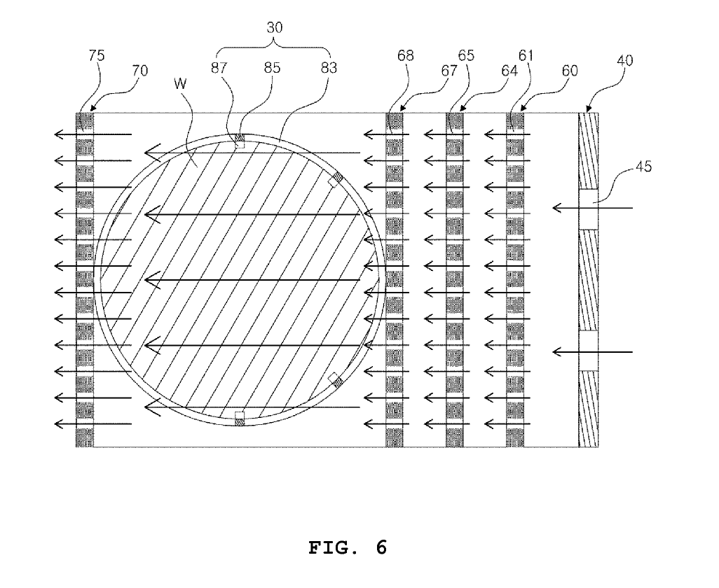

Hereinafter, exemplary embodiments of the present invention will be described in detail with reference to FIGS. 5 to 6. The present invention may, however, be embodied in different forms and should not be constructed as limited to the embodiments set forth herein. Rather, these embodiments are provided so that this disclosure will be thorough and complete, and will fully convey the scope of the present invention to those skilled in the art. In the drawings, the shapes of components are exaggerated for clarity of illustration.

FIG. 5 is a view of a substrate holder according to another embodiment of the present invention. FIG. 6 is a rear view illustrating a gas flow within a purge chamber in which the substrate holder of FIG. 5 is disposed. Referring to FIG. 5, a substrate holder 30 may have a boat-type shape including an upper frame 80 and a lower frame 83. The upper frame 80 is disposed above a substrate W, and a lower frame 83 is disposed under the substrate W. Each of the upper and lower frames 80 and 83 may have a circular shape corresponding to that of the substrate W.

A support rod 85 connects the upper frame 80 to the lower frame 83 and has a plurality of support slots 87. The processed substrate W is guided into the inner space 15 and is seated on the support slot 87 defined in the support rod 85. The support slot 87 may be defined in plurality along a length direction of the support rod 85. For example, three support slots 87 are defined to accommodate three substrates W.

Referring to FIG. 6, the boat-type substrate holder 30 may be further provided in the inner space 15 of the purge chamber 1 to minimize a contact area between the substrate W and the substrate holder 30. Thus, since a gas is supplied on the most area of the substrate W, the most corrosive fume remaining on the substrate W may be removed. Although not shown, since the holder cover 38 described with reference to FIG. 3 is disposed on the boat-type substrate holder 30, the chamber cover 38 may partition the inner space 15 to supply an maximum amount of gas introduced through the diffusion plates 60, 64, and 67 onto the substrate W.

That is, since the purge chamber 1 is connected to one side of the transfer chamber 170 to instantly transfers the processed substrate W from the process chambers 110 to the purge chamber 1, thereby removing the corrosive fume, other peripheral devices do not contact the fume remaining on the substrate W. Thus, the corrosion of the peripheral components and devices may be prevented to improve productivity and economic feasibility. In addition, since the most fume of the substrate is removed by using the substrate holder 30 according to the embodiments of the present invention, faulty of the processed substrates due to the fume may be prevented, and yield of products may be improved.

Although the present invention is described in detail with reference to the exemplary embodiments, the invention may be embodied in many different forms. Thus, technical idea and scope of claims set forth below are not limited to the preferred embodiments.

### INDUSTRIAL APPLICABILITY

The present invention is applicable for a semiconductor manufacturing apparatus and a semiconductor manufacturing method in a various type.

1. A substrate processing apparatus comprising:
a process chamber in which a process for processing a substrate are processed;
a purge chamber removing contaminants existing on the substrate; and
a transfer chamber connected to a side surface of each of the process chamber and the purge chamber, the transfer chamber comprising a substrate handler transferring the substrate, on which the process is performed, into the purge chamber between the process chamber and the purge chamber,
wherein the purge chamber comprises:
a chamber having an inner space and a passage through which the substrate is taken in or out of the inner space;
a substrate holder on which the substrate is placed, the substrate holder being disposed in the chamber;
a gas supply port disposed on a side surface with respect to the passage to supply a gas toward the inner space; and
an exhaust port disposed on a side opposite to the gas supply port to discharge the gas within the inner space.

2. The substrate processing apparatus of claim 1, wherein the purge chamber further comprises at least one diffusion plate disposed on a sidewall of the chamber connected to the gas supply port to diffuse the gas supplied through the gas supply port.

3. The substrate processing apparatus of claim 1, wherein the substrate holder comprises:
one or more loading plate having an opening with a shape corresponding to that of the substrate, an opening part defined in a side of the passage to communicate with the opening, and a seat groove defined along a circumference of the opening, wherein the one or more loading plats are vertically stacked on each other; and
a holder cover disposed spaced upward from the loading plate, the holder cover vertically partitioning the inner space.

4. The substrate processing apparatus of claim 1, wherein the substrate holder comprises:
an upper frame disposed above the substrate;
a lower frame disposed under the substrate; and
at least one support rod connecting the upper frame to the lower frame, the at least one support rod having a plurality support slots, in which an edge of the substrate is accommodated, defined along a length direction thereof.

5. The substrate processing apparatus of claim 1, wherein the purge chamber further comprises at least one baffle disposed on a sidewall of the chamber, to which the exhaust port is connected, to discharge the gas within the inner space.

6. The substrate processing apparatus of claim 1, wherein the gas has a flow direction perpendicular to an entrance direction of the substrate.

7. The substrate processing apparatus of claim 1, wherein the gas comprises an inert gas.

8. The substrate processing apparatus of claim 1, wherein the purge chamber further comprises a refrigerant passage in which a refrigerant supplied from the outside circulates.

9. A purge chamber comprising:
a chamber comprising an inner space and a passage through which a substrate is taken in or out of the inner space;
a substrate holder on which the substrate is placed, the substrate holder being disposed within a chamber;
a gas supply port disposed a side surface with respect to the passage to supply a gas toward the inner space; and
an exhaust port disposed a side opposite to the gas supply port to discharge the gas within the inner space,
wherein the substrate holder comprises:
one or more loading plate having an opening with a shape corresponding to that of the substrate, an opening part defined in a side of the passage to communicate with the opening, and a seat groove defined along a circumference of the opening, wherein the one or more loading plats are vertically stacked on each other; and
a holder cover disposed spaced upward from the loading plate, the holder cover vertically partitioning the inner space.

10. A purge chamber comprising:
a chamber comprising an inner space and a passage through which a substrate is taken in or out of the inner space;
a substrate holder on which the substrate is placed, the substrate holder being disposed within a chamber;
a gas supply port disposed a side surface with respect to the passage to supply a gas toward the inner space; and
an exhaust port disposed a side opposite to the gas supply port to discharge the gas within the inner space,
wherein the substrate holder comprises:
an upper frame disposed above the substrate;
a lower frame disposed under the substrate; and
at least one support rod connecting the upper frame to the lower frame, the at least one support rod having a plurality support slots, in which an edge of the substrate is accommodated, defined along a length direction thereof.
